(19) United States
(12) Patent Application Publication
(10) Pub. No.: US 2019/0206907 A1
(43) Pub. Date: Jul. 4, 2019

(54) ARRAY SUBSTRATE AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventors: Tian OU, Shenzhen (CN); Hongyuan XU, Shenzhen (CN)

(21) Appl. No.: 15/910,665

(22) Filed: Mar. 2, 2018

Related U.S. Application Data
(63) Continuation of application No. PCT/CN2018/074064, filed on Jan. 24, 2018.

(30) Foreign Application Priority Data
Dec. 28, 2017 (CN) 201711461556.0

(51) Int. Cl. H01L 27/12

(52) U.S. Cl. CPC H01L 27/1248; H01L 27/1288; H01L 27/1262

(57) ABSTRACT

An array substrate and a manufacturing method thereof are provided. The manufacturing method comprises: depositing a passivation material layer on a TFT layer, wherein the passivation material layer includes a first film layer and a second film layer made of different materials alternatively arranged; using a photoresist layer as a mask to etch the passivation material layer until the first film layer is exposed so as to form a patterned structure; depositing an ITO film on the photoresist layer and the exposed first film layer; and stripping the photoresist layer to form the array substrate. By using different materials with different etching speed, a greater gap between the boundary of the spacer and the boundary of the photoresist structure would be formed to facilitate the photoresist stripping process. Thereby, the stripping efficiency and the stripping uniformity can be enhanced to reduce the probability of photoresist residue.

### RELATED APPLICATIONS

The present application is a National Phase of International Application Number PCT/CN2018/074064, filed Jan. 24, 2018, and claims the priority of China Application No. 201711461556.0, filed Dec. 28, 2017.

### FIELD OF THE DISCLOSURE

The present invention is related to the technology about array substrate, and more particularly is related to an array substrate and a manufacturing method thereof.

### BACKGROUND

Thin film transistor liquid crystal display (TFT-LCD) is the most widely used flat panel display in present, and the manufacturing method of LCD panel became mature and advanced. In order to survive in the competitive business environment, it is important to simplify the manufacturing technology, reduce the manufacturing time, and enhance manufacturing efficiency to reduce the manufacturing cost. Therefore, 3Mask technology for manufacturing TFT-LCD array substrate structure had been widely researched.

3Mask technology is developed on the basis of 4Mask technology, with the usage of half-tone mask together with Lift-off technology of indium-tin oxide (ITO), to form the ITO film without removing the photoresist layer after the via in formed in the passivation layer, and to remove the photoresist layer after the ITO film is formed, such that the patterning process of the pixel electrode layer is completed together with the process of stripping the photoresist layer. The difficulty of the Lift-off technology of ITO is that, because the photoresist layer is covered by the ITO film, the stripping process using the stripping liquid can only be started from the exposed region of the photoresist layer. If the exposed region is small, the problems of low stripping efficiency and photoresist residue would be resulted to influence panel quality.

### SUMMARY

In order to resolve the insufficiency of the conventional technology, an array substrate and a manufacturing method thereof is provided in the present invention to enhance stripping efficiency and stripping uniformity so as to reduce the probability of photoresist residue.

A manufacturing method of an array substrate is provided in the present invention. The manufacturing method comprises the steps of: depositing a passivation material layer on a thin film transistor (TFT) layer, wherein the passivation material layer includes a first film layer and a second film layer alternatively disposed on the TFT layer, the second film layer is a top layer of the passivation material layer, and the first film layer and the second film layer are made of different materials; using a photoresist layer as a mask to etch the passivation material layer until the first film layer is exposed so as to form a patterned structure corresponding to the photoresist layer; depositing an indium-tin oxide (ITO) film on the photoresist layer and the exposed first film layer; and stripping the photoresist layer to form the array substrate.

In an embodiment, the first film layer is made of silicon dioxide, and the second film layer is made of silicon nitride.

In an embodiment, before the step of using a photoresist layer as a mask to etch the passivation material layer until the first film layer is exposed, the manufacturing method further comprises: depositing a photoresist material layer on the passivation material layer; and applying an exposure and development process to the photoresist material layer to form the photoresist layer including a plurality of photoresist structures spaced apart from each other.

In an embodiment, the patterned structure includes a plurality of spacers spaced apart from each other, and the spacers are corresponding to the photoresist structures one by one.

In an embodiment, a projection of the spacer on the first film layer is within a projection of the corresponding photoresist structure on the first film layer.

In an embodiment, a thickness of the ITO film is smaller than a thickness of the second film layer.

An array substrate is also provided in the present invention. The array substrate comprises a TFT layer, a passivation layer, and a pixel electrode layer. The passivation layer is located on the TFT layer, the pixel electrode layer is formed on the passivation layer, the passivation layer includes a first film layer, a second film layer and a patterned structure located on a top layer of the passivation layer, the first film layer and the second film layer are made of different materials, the pixel electrode layer includes a plurality of pixel electrodes, the patterned structure includes a plurality of spacers, and the spacers and the pixel electrodes are spaced apart from each other.

In an embodiment, the first film layer is made of silicon dioxide, and the second film layer is made of silicon nitride.

In an embodiment, a thickness of the pixel electrode is smaller than a thickness of the spacer.

In an embodiment, the passivation layer further has through holes thereon, and the pixel electrode is connected to a drain electrode of a TFT of the TFT layer through the through hole.

The manufacturing method of the array substrate provided in the present invention features the passivation material layer with the alternatively disposed first film layer and the second film layer. The first film layer and the second film layer are made of different materials, such that the first film layer and the second film layer may have different etching speeds during the etching process such that greater gap between the boundary of the spacer and the boundary of the photoresist layer would be formed to facilitate the photoresist stripping process using the stripping liquid. Thereby, stripping efficiency and stripping uniformity can be enhanced to reduce the probability of photoresist residue.

### BRIEF DESCRIPTION OF THE DRAWINGS

FIG. 1 is a structural schematic view of an array substrate.

FIG. 2 to FIG. 6 are schematic views showing the manufacturing method of the array substrate.

### DETAILED DESCRIPTION OF PREFERRED EMBODIMENTS

In the following description, the present invention will be further illustrated in detail in combination with accompanying drawings and embodiments hereinafter. However, the disclosure can be embodied in many forms of substitution, and should not be interpreted as merely limited to the embodiments described herein. In the contrary, the embodiments are for illustrating the principle of the invention and the practical application thereof in order to have a person skilled in the art to understand the embodiments described herein and the various substitutions. In the drawings, the same labels are used for representing the same elements.

Please refer to FIG. 1, the array substrate provided in the present embodiment includes a TFT layer 1, a passivation layer 2, and a pixel electrode layer 3. The passivation layer 2 is located on the TFT layer 1, the pixel electrode layer 3 is formed on the surface of the passivation layer 2. The passivation layer 2 includes a first film layer 21 and a second film layer 22, which are arranged alternatively, and a patterned structure 23 located on a top layer of the passivation layer 2. The first film layer 21 and the second film layer 22 are made of different materials. The patterned structure 23 and the second film layer 22 are made of the same material. The pixel electrode layer 3 includes a plurality of pixel electrodes 31. The patterned structure 23 includes a plurality of spacers 230. The spacers 230 and the pixel electrodes 31 are spaced apart from each other.

The bottom layer of the passivation layer 2 can be the first film layer 21 or the second film layer 22, i.e. the passivation layer 2 can be arranged by stacking the first film layer 21 and the second film layer 22 alternatively from the bottom to the top, or the second film layer 22 and the first film layer 21 alternatively from the bottom to the top. The top layer of the passivation layer 2 is the patterned structure 23.

FIG. 1 of the present embodiment only shows a pixel structure of the pixel electrode layer 3 corresponding to multiple pixel electrodes 31. The pixel electrodes 31 of the same pixel structure are arranged as a comb, and these pixel electrodes 31 are connected together. The TFT layer 1 includes a substrate 11 and TFTs. In FIG. 1, only the TFT of a pixel structure is shown. The TFT is corresponding to the multiple pixel electrodes 31. The TFT includes a gate insulation layer 12, a gate electrode 13, an active layer 14, a source electrode 15, and a drain electrode 16. The TFT is a bottom-gate structure, and the gate electrode 13 is located on the substrate 11. The gate insulation layer 12 covers the gate electrode 13 and the substrate 1. The active layer 14 is located on the gate insulation layer 12. The gate electrode 13 and the active layer 14 are separated by the gate insulation layer 12. The source electrode 15 and the drain electrode 16 are located at the two sides of the active layer 14 and partially cover the active layer 14 respectively. The passivation layer 2 covers the active layer 14, the source electrode 15, and the drain electrode 16. The TFT is made of ITO.

The first film layer 21 is made of silicon dioxide. The second film layer 22 is made of silicon nitride. The patterned structure 23 is also made of silicon nitride. The first film layer 21 and the second film layer 22 can be made of the other materials with the only limitation that the reaction speed of the material of the second film layer 22 should be greater than the reaction speed of the material of the first film layer 21 when forming the patterned structure 23.

In the present embodiment, the thickness of the pixel electrode 31 is smaller than the thickness of the spacer 230, i.e. the height of the pixel electrode 31 along the direction perpendicular to the substrate 11 is smaller than the height of the spacer 230 along the direction perpendicular to the substrate 11.

The passivation layer 2 has a through hole 20 thereon, and one of the pixel electrodes 31 is connected to the drain electrode 16 of the TFT through the through hole 20.

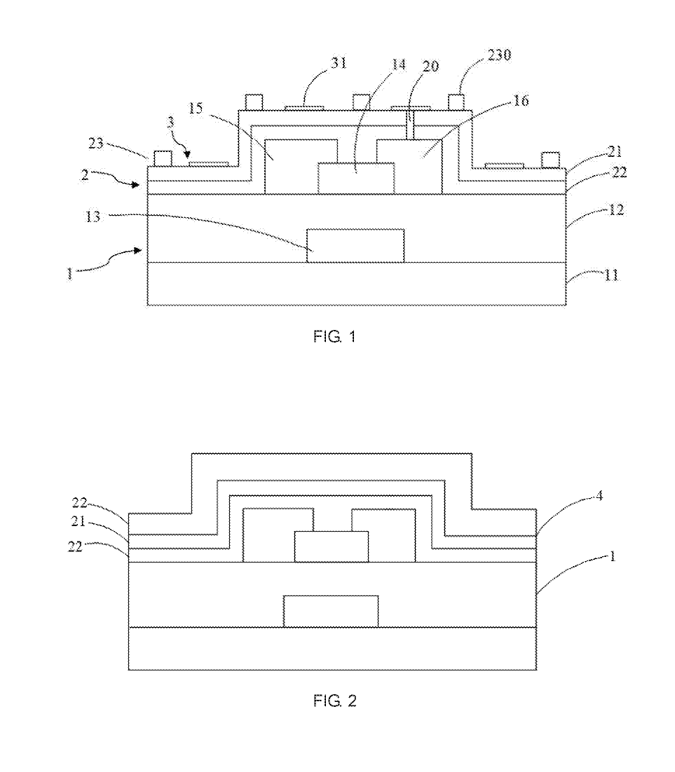

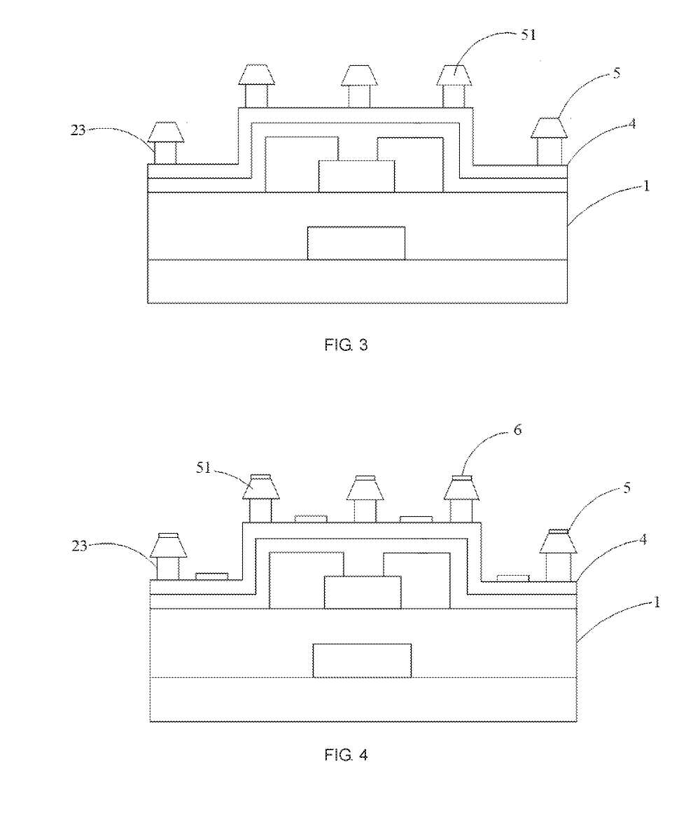

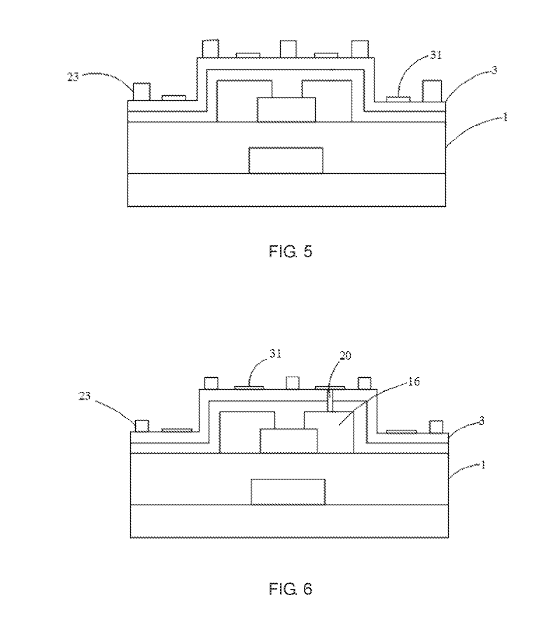

Please refer to FIG. 2 to FIG. 6, the manufacturing method of the aforementioned array substrate is also provided in accordance with an embodiment of the present invention. The manufacturing method comprises the steps of:

S1, depositing a passivation material layer 4 on a TFT layer 1, wherein the passivation material layer 4 includes a first film layer 21 and a second film layer 22 alternatively disposed on the TFT layer 1, the second film layer 22 is a top layer of the passivation material layer 4, and the first film layer 21 and the second film layer 22 are made of different materials;

S2, using a photoresist layer 5 as a mask to etch the passivation material layer 4 until the first film layer 21 is exposed so as to form a patterned structure 23 corresponding to the photoresist layer 5:

S3, depositing an ITO film 6 on the photoresist layer 5 and the exposed first film layer 21, wherein a thickness of the ITO film 6 is smaller than a thickness of the second film layer 22; and

S4, stripping the photoresist layer 5 to form the array substrate.

In step S4, after the photoresist layer 5 is stripped, the ITO film 6 on the photoresist layer 5 is also stripped, and only the ITO film 6 formed on the first film layer 21 is left such that the pixel electrode layer 3 is formed on the surface of the first film layer 21, and the ITO films 6 spaced apart from each other as the pixel electrodes 31 of the pixel electrode layer 3.

After the photoresist layer 5 is stripped in step S4, the through hole 20 needs to be formed such that the pixel electrode 31 can be connected to the drain electrode 16 of the TFT through the through hole 20 as shown in FIG. 6.

The bottom layer of the passivation material layer 4 can be the first film layer 21 or the second film layer 22, i.e. the passivation material layer 4 can be arranged by stacking the first film layer 21 and the second film layer 22 alternatively from the bottom to the top, or the second film layer 22 and the first film layer 21 alternatively from the bottom to the top. The top layer of the passivation material layer 4 is the second film layer 22. For example, the passivation layer 4 may include two layers, i.e. the first film layer 21 as the bottom layer and the second film layer 22 as the top layer, or include three layers, i.e. the second film layers 22 as the bottom layer and the top layer, and the first film layer 21 as the middle layer.

The first film layer 21 is made of silicon dioxide. The second film layer 22 is made of silicon nitride. The first film layer 21 and the second film layer 22 can be made of the other materials with the only limitation that the etching speed of the second film layer 22 should be greater than the etching speed of the first film layer 21.

Before the step S2, the manufacturing method further comprises:

S01, depositing a photoresist material layer 7 on the passivation material layer 4; and

S02, applying an exposure and development process to the photoresist material layer 7 to form the photoresist layer 5 including a plurality of photoresist structures 51 spaced apart from each other.

The patterned structure 23 includes a plurality of spacers 230 spaced apart from each other. These spacers 230 are corresponding to the photoresist structures 51 one by one.

Preferably, the projection of the spacer 230 on the first film layer 21 is within the projection of the photoresist structure 51 on the first film layer. That is, the size of the spacer 230 is smaller than the size of the photoresist structure 51.

The passivation material layer 4 in the present embodiment includes the alternatively arranged first film layer 21 and the second film layer 22. The first film layer 21 and the second film layer 22 are made of different materials with different etching speed during the etching process, such that a greater gap between the boundary of the spacer 230 and the boundary of the photoresist structure 51 would be formed to facilitate the photoresist stripping process for stripping the photoresist structure 51 using the stripping liquid. Thereby, the stripping efficiency and the stripping uniformity can be enhanced to reduce the probability of photoresist residue of the photoresist structures 51.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

1. A manufacturing method of an array substrate, comprising the steps of:
depositing a passivation material layer on a thin film transistor (TFT) layer, wherein the passivation material layer includes a first film layer and a second film layer alternatively disposed on the TFT layer, the second film layer is a top layer of the passivation material layer, and the first film layer and the second film layer are made of different materials;
using a photoresist layer as a mask to etch the passivation material layer until the first film layer is exposed so as to form a patterned structure corresponding to the photoresist layer, wherein the patterned structure includes a plurality of spacers spaced apart from each other, the spacers are corresponding to the photoresist structures one by one, and a height of the pixel electrode along a direction perpendicular to the substrate is smaller than a height of the spacer along the direction perpendicular to the substrate;
depositing an indium-tin oxide (ITO) film on the photoresist layer and the exposed first film layer; and
stripping the photoresist layer to form the array substrate.

2. The manufacturing method of claim 1, wherein the first film layer is made of silicon dioxide, and the second film layer is made of silicon nitride.

3. The manufacturing method of claim 1, wherein before the step of using a photoresist layer as a mask to etch the passivation material layer until the first film layer is exposed, the manufacturing method further comprises:
depositing a photoresist material layer on the passivation material layer;
applying an exposure and development process to the photoresist material layer to form the photoresist layer including a plurality of photoresist structures spaced apart from each other.

4. (canceled)

5. The manufacturing method of claim 3, wherein a projection of the spacer on the first film layer is within a projection of the corresponding photoresist structure on the first film layer.

6. The manufacturing method of claim 1, wherein a thickness of the ITO film is smaller than a thickness of the second film layer.

7. An array substrate, comprising a TFT layer, a passivation layer, and a pixel electrode layer, wherein the passivation layer is located on the TFT layer, the pixel electrode layer is formed on the passivation layer, the passivation layer includes a first film layer, a second film layer and a patterned structure located on a top layer of the passivation layer, the first film layer and the second film layer are made of different materials, the pixel electrode layer includes a plurality of pixel electrodes, the patterned structure includes a plurality of spacers, the spacers and the pixel electrodes are spaced apart from each other, and a height of the pixel electrode along a direction perpendicular to the substrate is smaller than a height of the spacer along the direction perpendicular to the substrate.

8. The array substrate of claim 7, wherein the first film layer is made of silicon dioxide, and the second film layer is made of silicon nitride.

9. (canceled)

10. The array substrate of claim 7, wherein the passivation layer further has through holes thereon, and the pixel electrode is connected to a drain electrode of a TFT of the TFT layer through the through holes.
